(19) United States
(12) Patent Application Publication
(10) Pub. No.: US 2024/0014667 A1
(43) Pub. Date: Jan. 11, 2024

(54) ENERGY STORAGE SYSTEM AND CONTROL METHOD THEREOF

(71) Applicant: Huawei Digital Power Technologies Co., Ltd., Shenzhen (CN)

(72) Inventors: Zhipeng Wu, Shenzhen (CN); Yanbai Shen, Shanghai (CN); Shijiang Yu, Shanghai (CN)

(21) Appl. No.: 18/472,056

(22) Filed: Sep. 21, 2023

Related U.S. Application Data
(63) Continuation of application No. PCT/CN2021/083274, filed on Mar. 26, 2021.

(51) Int. Cl. H02J 7/00

(52) U.S. Cl. CPC H02J 7/0014; H02J 7/00712; H02J 2207/20

(57) ABSTRACT

An energy storage system includes at least one battery cluster, at least two direct current DC/DC conversion modules, and a control unit. An output end of each battery cluster is connected to an input end of each DC/DC conversion module with a switch, and output ends of the at least two DC/DC conversion modules are connected in parallel to a direct current bus. The control unit is connected to each battery cluster and each DC/DC conversion module with a control bus, to control charging and discharging of each battery cluster and control each DC/DC conversion module to perform direct current conversion. The control unit is further configured to control turn-on or turn-off of a switch used by each battery cluster to connect to each DC/DC conversion module, so as to control connections between each battery cluster and different quantities of DC/DC conversion modules.

### CROSS-REFERENCE TO RELATED APPLICATIONS

This application is a continuation of International Application No. PCT/CN2021/083274, filed on Mar. 26, 2021, the disclosure of which is hereby incorporated by reference in its entirety.

### TECHNICAL FIELD

This application relates to the field of battery energy storage technologies, and in particular, to an energy storage system and a control method thereof.

### BACKGROUND

With occurrence of environmental problems and continuous exhaustion of fossil fuel reserves, renewable energy such as wind energy and solar energy gradually becomes a main research direction. Although new clean energy in wind power generation, photovoltaic power generation, and the like has an innate advantage of being inexhaustible, such energy is affected by terrains, climates, and environments, and therefore has disadvantages of low stability and low reliability. Based on this, energy storage technologies have emerged. The essence of energy storage technologies is conversion of energy forms. Energy may be stored in various media, and then converted into electric energy when needed. In the smart grid field and the automobile field, an energy storage system in which a battery is used as an energy storage device has a good development prospect. Generally, different energy storage systems have different rated charge/discharge rates. To adapt to various charge/discharge rate scenarios, current energy storage systems are mostly developed in a customized manner. For example, in the case of a same battery capacity, to match with different rated charge/discharge rates, power converters of different specifications need to be designed. As a result, power converter specifications are numerous, and development costs are comparatively high. Therefore, how to design an energy storage system compatible with different rated charge/discharge rates and reduce development costs becomes one of problems to be urgently resolved at present.

### SUMMARY

This application provides an energy storage system and a control method thereof, which can be compatible with different rated charge/discharge rates, thereby reducing development costs of an energy storage system and achieving high applicability.

According to a first aspect, this application provides an energy storage system. The energy storage system includes at least one battery cluster, at least two direct current DC/DC conversion modules, and a control unit. An output end of each of the at least one battery cluster is connected to an input end of each of the at least two DC/DC conversion modules by using a switch, and output ends of the at least two DC/DC conversion modules are connected in parallel to a direct current bus. The control unit is connected to the at least one battery cluster and each of the at least two DC/DC conversion modules by using a control bus, to control charging and discharging of the at least one battery cluster and control each of the at least two DC/DC conversion modules to perform direct current conversion. The control unit is further configured to control turn-on or turn-off of a switch used by each of the at least one battery cluster to connect to each of the at least two DC/DC conversion modules, to control connections between each of the at least one battery cluster and different quantities of DC/DC conversion modules, thereby controlling a rated charge/discharge rate of the energy storage system. It can be understood that the DC/DC conversion module may be a bidirectional DC/DC conversion circuit. The switch may be a circuit breaker, a contactor, or the like.

In this application, from the perspective of a connection relationship, each battery cluster included in the energy storage system may be connected to the DC/DC conversion modules; during actual running, turn-on and turn-off of switches used for connections between each battery cluster and the DC/DC conversion modules are controlled by using the control unit, so as to control a quantity of DC/DC conversion modules correspondingly connected to each battery cluster, thereby controlling the rated charge/discharge rate of the energy storage system. Usually, the rated charge/discharge rate of the energy storage system is directly proportional to a quantity of DC/DC conversion modules correspondingly connected to the battery cluster in the energy storage system. For example, there is one battery cluster. In this case, when the battery cluster is correspondingly connected to one DC/DC conversion module, the rated charge/discharge rate of the energy storage system is XC; or when the battery cluster is correspondingly connected to n DC/DC conversion modules, the rated charge/discharge rate of the energy storage system is nXC, where n is an integer greater than 1. A specific value of X is determined based on a matching status between a rated capacity of the battery cluster and rated operating power of the DC/DC conversion module. In other words, the value of X is determined based on specifications of the battery cluster and the DC/DC conversion module.

With reference to the first aspect, in a first possible implementation, the at least one battery cluster includes a first battery cluster; and the control unit is configured to control a switch, which is used by the first battery cluster to connect to a first DC/DC conversion module in the at least two DC/DC conversion modules, to be turned on, and control a switch, which is used by the first battery cluster to connect to a DC/DC conversion module that is other than the first DC/DC conversion module and that is in the at least two DC/DC conversion modules, to be turned off, thereby controlling a charge/discharge current of the energy storage system, so that the rated charge/discharge rate of the energy storage system is a first rated charge/discharge rate.

In this application, if each battery cluster included in the energy storage system joins in running (e.g., each battery cluster is correspondingly connected to a DC/DC conversion module), each battery cluster in the energy storage system is correspondingly connected to a same quantity of DC/DC conversion modules, and one connected DC/DC conversion module can correspond to only one battery cluster. Herein, the first battery cluster is used as an example. When the first battery cluster is correspondingly connected to one DC/DC conversion module (e.g., the first DC/DC conversion module), the rated charge/discharge rate of the energy storage system is XC, where a magnitude of X is determined based on specifications of the battery cluster and the DC/DC conversion module.

With reference to the first possible implementation of the first aspect, in a second possible implementation, the control unit is further configured to control switches, which are used by the first battery cluster to connect to n DC/DC conversion modules in the at least two DC/DC conversion modules, to be turned on, and control a switch, which is used by the first battery cluster to connect to a DC/DC conversion module that is other than the n DC/DC conversion modules and that is in the at least two DC/DC conversion modules, to be turned off, thereby controlling a charge/discharge current of the energy storage system, so that the rated charge/discharge rate of the energy storage system is a second rated charge/discharge rate, where the n DC/DC conversion modules or the another DC/DC conversion module include/includes the first DC/DC conversion module, the second rated charge/discharge rate is n times the first rated charge/discharge rate, and n is an integer greater than 1.

In this application, if each battery cluster included in the energy storage system joins in running (e.g., each battery cluster is correspondingly connected to a DC/DC conversion module), each battery cluster in the energy storage system is correspondingly connected to a same quantity of DC/DC conversion modules, and one connected DC/DC conversion module can correspond to only one battery cluster. Herein, the first battery cluster is used as an example. When the first battery cluster is correspondingly connected to n DC/DC conversion modules, the rated charge/discharge rate of the energy storage system is nXC, where a magnitude of X is determined based on specifications of the battery cluster and the DC/DC conversion module.

With reference to the first aspect, in a third possible implementation, the energy storage system includes at least two battery clusters, and the at least two battery clusters include a first battery cluster and a second battery cluster. The control unit is configured to control a switch, which is used by the first battery cluster to connect to h DC/DC conversion modules in the at least two DC/DC conversion modules, to be turned on, control a switch, which is used by the first battery cluster to connect to a DC/DC conversion module that is other than the h DC/DC conversion modules and that is in the at least two DC/DC conversion modules, to be turned off, and control a switch, which is used by the second battery cluster to connect to each of the at least two DC/DC conversion modules, to be turned off, thereby controlling a charge/discharge current of the energy storage system, so that the rated charge/discharge rate of the energy storage system is a target rated charge/discharge rate, where h is an integer greater than 0.

In this application, if a battery cluster in the energy storage system does not join in running, that is, the battery cluster is not correspondingly connected to any DC/DC conversion module, a quantity of DC/DC conversion modules correspondingly connected to each running battery cluster is controlled to be 1 or greater than 1, so that different rated charge/discharge rates of the energy storage system can also be controlled.

With reference to any one of the first aspect, or the first to the third possible implementations of the first aspect, in a fourth possible implementation, the control unit is further configured to control charging and discharging of each battery cluster based on an output current magnitude and initial state of charge of the battery cluster, to balance remaining power of each battery cluster.

In this application, when the energy storage system includes at least two battery clusters that are in a running state (e.g., each battery cluster is correspondingly connected to a same quantity of different DC/DC conversion modules), the control unit may control charging and discharging of each of the at least two battery clusters by using an output current magnitude and initial state of charge of the battery cluster that are obtained, to balance remaining power of each battery cluster, thereby reducing inconsistency between the battery clusters in charging and discharging processes, and avoiding overcharge and overdischarge of the battery cluster.

With reference to the fourth possible implementation of the first aspect, in a fifth possible implementation, each battery cluster includes at least one battery module connected in series, each battery module includes one battery management unit BMU, the control unit is connected to a BMU of each battery module in each battery cluster by using the control bus, and the control unit is configured to obtain an initial state of charge of each battery cluster by using a BMU of each battery module.

In this application, a BMU in each battery module in the battery cluster may be configured to monitor signals such as a cell voltage, a temperature, and an initial state of charge in the battery module, to implement charging and discharging management and control of each battery cluster, thereby avoiding damage to the battery cluster.

With reference to the fourth possible implementation of the first aspect, in a sixth possible implementation, each of the at least two DC/DC conversion modules includes one battery control unit BCU, the control unit is connected to each BCU in the DC/DC conversion modules by using the control bus, and the control unit is configured to obtain an output current magnitude of each battery cluster by using each BCU.

In this application, an output current of each battery cluster is collected based on a BCU included in each DC/DC conversion module, and may be used to implement charging and discharging management and control of each battery cluster, thereby helping improve stability and reliability of the energy storage system.

With reference to the fourth possible implementation of the first aspect, in a seventh possible implementation, the at least two DC/DC conversion modules include one battery control unit BCU, the control unit is connected to the BCU by using the control bus, and the control unit is configured to obtain an output current magnitude of each battery cluster by using the BCU.

In this application, one BCU is reused to collect output currents of all battery clusters, so that complexity of the energy storage system can be reduced, and applicability is high.

With reference to any one of the first aspect, or the first to the seventh possible implementations of the first aspect, in an eighth possible implementation, the energy storage system further includes a power converter, an input end of the power converter is connected to the direct current bus, an output end of the power converter is connected to an alternating current bus, and the power converter is configured to convert, into alternating current electricity during discharging of the battery cluster, direct current electricity that is input based on the direct current bus, or the power converter is configured to convert, into direct current electricity during charging of the battery cluster, alternating current electricity that is input based on the alternating current bus.

In this application, the power converter is configured to convert, into alternating current electricity during discharging of the battery cluster, direct current electricity that is input based on the direct current bus, or the power converter is configured to convert, into direct current electricity during charging of the battery cluster, alternating current electricity that is input based on the alternating current bus. This enhances applicability of the energy storage system.

According to a second aspect, this application provides an energy storage system control method. The method is applicable to an energy storage system. The energy storage system includes at least one battery cluster, at least two direct current DC/DC conversion modules, and a control unit. An output end of each of the at least one battery cluster is connected to an input end of each of the at least two DC/DC conversion modules by using a switch, output ends of the at least two DC/DC conversion modules are connected in parallel to a direct current bus, and the control unit is connected to the at least one battery cluster and each of the at lease two DC/DC conversion modules by using a control bus. Specifically, the method includes: first, controlling turn-on or turn-off of a switch used by each of the at least one battery cluster to connect to each of the at least two DC/DC conversion modules, to control connections between each of the at least one battery cluster and different quantities of DC/DC conversion modules; then, obtaining an output current magnitude and initial state of charge of each battery cluster; and further, controlling charging and discharging of each battery cluster based on an output current magnitude and initial state of charge of the battery cluster, to balance remaining power of each battery cluster.

With reference to the second aspect, in a first possible implementation, the controlling charging and discharging of each battery cluster based on an output current magnitude and initial state of charge of the battery cluster includes: controlling, based on an output current magnitude and initial state of charge of each battery cluster, operating power of each DC/DC conversion module correspondingly connected to the battery cluster, to control charging and discharging of each battery cluster.

With reference to the first possible implementation of the second aspect, in a second possible implementation, the controlling, based on an output current magnitude and initial state of charge of each battery cluster, operating power of each DC/DC conversion module correspondingly connected to the battery cluster includes: determining, based on an output current magnitude and initial state of charge of any battery cluster, a first state of charge corresponding to the any battery cluster; and controlling, based on a first state of charge corresponding to each battery cluster, operating power of each DC/DC conversion module correspondingly connected to the battery cluster, to control charging and discharging of each battery cluster.

In this application, the control unit controls turn-on or turn-off of a switch used by the battery cluster to connect to each DC/DC conversion module, to enable a connection between the battery cluster and one or more DC/DC conversion modules, thereby controlling a rated charge/discharge rate of the energy storage system, so that the energy storage system can be compatible with different charge/discharge rates. In this way, development costs are reduced, and applicability is high. Further, in actual running, operating power of each DC/DC conversion module correspondingly connected to each battery cluster is controlled, to control charging and discharging of each battery cluster, thereby balancing remaining power of each battery cluster, and avoiding overcharge or overdischarge of the battery cluster. This helps improve stability and reliability of the energy storage system.

### BRIEF DESCRIPTION OF THE DRAWINGS

FIG. 1 is a schematic diagram of a system architecture of an energy storage system;

FIG. 2 is a schematic diagram of a structure of an energy storage system according to this application;

FIG. 3(a) to FIG. 3(c) are a schematic diagram of an application scenario of different rated charge/discharge rates according to an embodiment of this application;

FIG. 4 is a schematic diagram of another structure of an energy storage system according to this application;

FIG. 5(a) to FIG. 5(d) are a schematic diagram of another application scenario of different rated charge/discharge rates according to an embodiment of this application;

FIG. 6 is a schematic diagram of another structure of an energy storage system according to this application;

FIG. 7 is a schematic diagram of another structure of an energy storage system according to this application;

FIG. 8 is a schematic diagram of another structure of an energy storage system according to this application;

FIG. 9 is a schematic flowchart of an energy storage system control method according to this application; and

FIG. 10 is a schematic diagram of controlling a DC/DC conversion module according to this application.

### DETAILED DESCRIPTION OF ILLUSTRATIVE EMBODIMENTS

An energy storage system provided in this application is applicable to a plurality of types of power generation devices such as a photovoltaic power generation device or a wind power generation device and different types of electric devices (such as a power grid, a household device, an industrial electric device, or a commercial electric device), and may be applied to the automobile field, the micro-grid field, and the like. The energy storage system provided in this application is applicable to energy storage of different types of electrochemical batteries. Herein, the different types of electrochemical batteries may include a lithium-ion battery, a lead-acid battery (also referred to as a lead-acid battery), a lead-carbon battery, a supercapacitor, a solid-state battery, a flow battery, and the like. A specific battery type is not specifically limited in this application. For ease of description, in this application, the energy storage system provided in this application is described by using a lithium battery as an example.

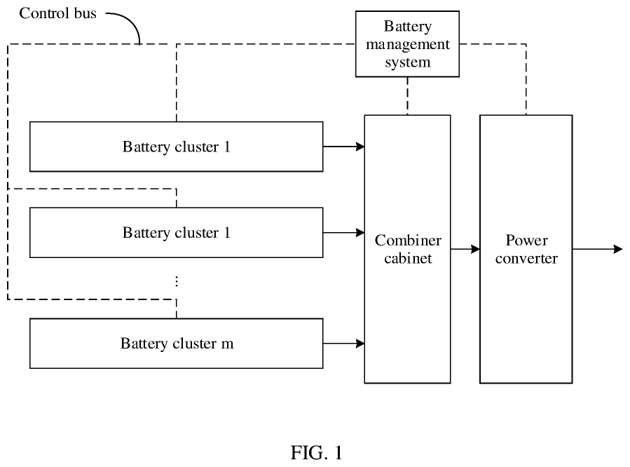

Energy storage systems are applied to an extensive range of scenarios, and are well applied in stages such as power generation, power transmission, power transformation, power distribution, and electricity consumption of power systems. Moreover, charge/discharge rates of energy storage systems are distributed in a wide range from 0.2C to 2C. Therefore, energy storage systems differ greatly. To adapt to a large quantity of charge/discharge rates, current energy storage systems are mostly developed in a customized manner, that is, one charge/discharge rate usually corresponds to one system structure and a converter of one specification. As a result, converter specifications are numerous, system costs are comparatively high, and a project development period is comparatively long. FIG. 1 is a schematic diagram of a system architecture of an energy storage system. The energy storage system shown in FIG. 1 includes a plurality of battery clusters (a battery cluster 1, a battery cluster 2, . . . , and a battery cluster m that are shown in FIG. 1), a combiner cabinet, and a power converter. After the plurality of battery clusters are connected in parallel through the combiner cabinet, the plurality of battery clusters are connected to a direct current side of the power converter. An external battery management system (battery management system, BMS) is connected to each battery cluster, the combiner cabinet, and the power converter by using a control bus. The BMS is configured to collect battery information of each battery cluster and communicate with the combiner cabinet and the power converter, to perform charging and discharging control on the energy storage system. It can be understood that a charge/discharge rate is a current value required for a battery to discharge a rated capacity of the battery within a specified time, is equal to a multiple of the rated capacity of the battery in terms of a numerical value, and is usually represented by a letter C. Usually, a charge/discharge rate is equal to a charge/discharge current (in amperes) divided by a rated battery capacity (in ampere hours), or a charge/discharge rate is equal to charge/discharge power (in kilowatts) divided by a rated battery capacity (in kilowatt-hours).

For the energy storage system shown in FIG. 1, in the case of a same battery capacity, to match with different rated charge/discharge rates, power converters of different specifications need to be designed. As a result, power converter specifications are numerous, and development costs are comparatively high. In addition, in the energy storage system shown in FIG. 1, the battery clusters are connected in parallel through the combiner cabinet. Therefore, during actual running of the energy storage system shown in FIG. 1, charging and discharging of the battery clusters in the energy storage system can be controlled only in a unified manner. However, there is a difference/inconsistency between different battery clusters, for example, different battery clusters have different electrochemical characteristics, or performance and various parameters of different battery clusters change to different extents as a quantity of charge/discharge cycles increases. Therefore, in actual running, if charging and discharging of the battery clusters in the energy storage system can be controlled only in a unified manner, some of the battery clusters may be overcharged or overdischarged, which seriously affects a battery lifespan. This is not conducive to stable running of the energy storage system.

Based on this, this application proposes an energy storage system. The energy storage system is compatible with different rated charge/discharge rates, and can implement independent running management of each battery cluster in the energy storage system. The energy storage system includes at least one battery cluster, at least two direct current (direct current, DC)/DC conversion modules, and a control unit. Usually, the control unit may be a central monitoring unit (CMU) or the like. This is not limited herein. An output end of each of the at least one battery cluster is connected to an input end of each of the at least two DC/DC conversion modules by using a switch, and output ends of the at least two DC/DC conversion modules are connected in parallel to a direct current bus. The at least two DC/DC conversion modules may be integrated into one direct current converter. Therefore, that the output ends of the at least two DC/DC conversion modules are connected in parallel to the direct current bus may be understood as follows: Positive electrodes of all the at least two DC/DC conversion modules are connected in parallel, and negative electrodes of all the at least two DC/DC conversion modules are connected in parallel, so as to be used as an output end of the direct current converter to connect to the direct current bus. The control unit is connected to the at least one battery cluster and each of the at least two DC/DC conversion modules by using a control bus, to control charging and discharging of the at least one battery cluster and control each of the at least two DC/DC conversion modules to perform direct current conversion. It can be understood that the control unit is further configured to control turn-on or turn-off of a switch used by each of the at least one battery cluster to connect to each of the at least two DC/DC conversion modules, to control connections between each of the at least one battery cluster and different quantities of DC/DC conversion modules, thereby controlling a rated charge/discharge rate of the energy storage system.

It can be understood that, if each battery cluster included in the energy storage system joins in running (e.g., each battery cluster is correspondingly connected to a DC/DC conversion module), each battery cluster in the energy storage system should be correspondingly connected to a same quantity of DC/DC conversion modules, and one connected DC/DC conversion module corresponds to one battery cluster. One battery cluster (e.g., a first battery cluster) in the energy storage system is used as an example. The control unit is configured to control a switch, which is used by the first battery cluster to connect to a first DC/DC conversion module in the at least two DC/DC conversion modules, to be turned on, and control a switch, which is used by the first battery cluster to connect to a DC/DC conversion module that is other than the first DC/DC conversion module and that is in the at least two DC/DC conversion modules, to be turned off, thereby controlling a charge/discharge current of the energy storage system, so that the rated charge/discharge rate of the energy storage system is a first rated charge/discharge rate. For example, when the first battery cluster is correspondingly connected to one DC/DC conversion module (e.g., the first DC/DC conversion module), the rated charge/discharge rate of the energy storage system is XC, where a magnitude of X is determined based on specifications of the battery cluster and the DC/DC conversion module.

Further, the control unit is further configured to control switches, which are used by the first battery cluster to connect to n DC/DC conversion modules in the at least two DC/DC conversion modules, to be turned on, and control a switch, which is used by the first battery cluster to connect to a DC/DC conversion module that is other than the n DC/DC conversion modules and that is in the at least two DC/DC conversion modules, to be turned off, thereby controlling a charge/discharge current of the energy storage system, so that the rated charge/discharge rate of the energy storage system is a second rated charge/discharge rate. The n DC/DC conversion modules or the another DC/DC conversion module include/includes the first DC/DC conversion module, the second rated charge/discharge rate is n times the first rated charge/discharge rate, and n is an integer greater than 1. For example, when the first battery cluster is correspondingly connected to n DC/DC conversion modules, the rated charge/discharge rate of the energy storage system is nXC, where a magnitude of X is determined based on specifications of the battery cluster and the DC/DC conversion module. During switching of the rated charge/discharge rate of the energy storage system, for example, switching the rated charge/discharge rate of the energy storage system from XC to nXC, a switch corresponding to (n−1) DC/DC conversion modules may be turned on in addition to turning on the switch corresponding to the first DC/DC conversion module, so that the first battery cluster is correspondingly connected to the n DC/DC conversion modules. Optionally, alternatively, the switch corresponding to the first DC/DC conversion module may be first turned off, and then switches corresponding to n DC/DC conversion modules are turned on, so that the first battery cluster is correspondingly connected to the n DC/DC conversion modules. This is not limited herein.

In other words, the control unit in this application controls turn-on or turn-off of a switch used by each battery cluster to connect to each DC/DC conversion module, to control connections between each battery cluster and different quantities of DC/DC conversion modules, thereby controlling the rated charge/discharge rate of the energy storage system. For example, the energy storage system includes one battery cluster. When the battery cluster is correspondingly connected to one DC/DC conversion module, the rated charge/discharge rate of the energy storage system is XC. When the battery cluster is correspondingly connected to n DC/DC conversion modules, the rated charge/discharge rate of the energy storage system is nXC. A specific value of X is determined based on a matching status between a rated capacity of the battery cluster and rated operating power of the DC/DC conversion module. In other words, X is determined based on specifications of the selected battery cluster and DC/DC conversion module. For example, it is assumed that a ratio of the rated operating power of the DC/DC conversion module in the energy storage system to the battery capacity of the battery cluster is 1:4. In this case, when the battery cluster is correspondingly connected to one DC/DC conversion module, the rated charge/discharge rate of the energy storage system is 0.25C, e.g., X=0.25. Correspondingly, when the battery cluster is correspondingly connected to two DC/DC conversion modules, the rated charge/discharge rate of the energy storage system is 0.5C. The rest may be deduced by analogy. When the battery cluster is correspondingly connected to n DC/DC conversion modules, the rated charge/discharge rate of the energy storage system is 0.25 nC. For another example, it is assumed that a ratio of the rated operating power of the DC/DC conversion module in the energy storage system to the battery capacity of the battery cluster is 1:2. In this case, when the battery cluster is correspondingly connected to one DC/DC conversion module, the rated charge/discharge rate of the energy storage system is 0.5C, e.g., X=0.5. Correspondingly, when the battery cluster is correspondingly connected to two DC/DC conversion modules, the rated charge/discharge rate of the energy storage system is 1C. The rest may be deduced by analogy. When the battery cluster is correspondingly connected to n DC/DC conversion modules, the rated charge/discharge rate of the energy storage system is 0.5 nC.

It can be understood that, in this embodiment of this application, the switch for connecting the battery cluster and the DC/DC conversion module may be a circuit breaker, a contactor, or the like. This is specifically determined based on an actual application scenario, and is not limited herein. The DC/DC conversion module is a bidirectional DC/DC conversion circuit, and all the DC/DC conversion modules in this application are the same. Usually, the bidirectional DC/DC conversion circuit may be a non-isolated bidirectional DC/DC conversion circuit, an isolated bidirectional DC/DC conversion circuit, or the like. This is not limited herein. The non-isolated bidirectional DC/DC conversion circuit may include a flying capacitor multilevel circuit, a three-level boost circuit, a four-switch buck-boost circuit, or the like. This is not limited herein. A switching device used in the DC/DC conversion circuit may be a metal-oxide semiconductor field-effect transistor (metal-oxide semiconductor field-effect transistor, MOSFET), an insulated gate bipolar transistor (insulated gate bipolar transistor, IGBT), or the like made of a material such as a semiconductor silicon (silicon, Si) material or silicon carbide (silicon carbide, SiC) or gallium nitride (gallium nitride, GaN) of a third-generation wide-bandgap semiconductor material. This is not limited herein.

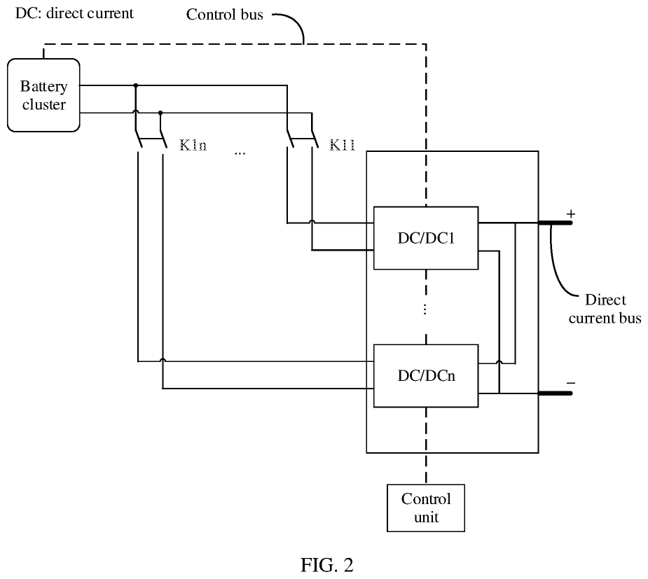

The following describes the energy storage system provided in this application and a working principle of the energy storage system by using examples with reference to FIG. 2 to FIG. 9.

FIG. 2 is a schematic diagram of a structure of an energy storage system according to this application. As shown in FIG. 2, the energy storage system includes one battery cluster, n DC/DC conversion modules, and a control unit, where n is an integer greater than 1. In other words, the n DC/DC conversion modules may be a DC/DC conversion module 1, . . . , and a DC/DC conversion module n. An output end of the battery cluster may be connected to the DC/DC conversion module 1 (DC/DC1 shown in FIG. 2) by using a switch K11, the output end of the battery cluster may be further connected to a DC/DC conversion module 2 (not shown in FIG. 2) by using a switch K12 (not shown in FIG. 2), . . . , and the output end of the battery cluster may be further connected to the DC/DC conversion module n (DC/DCn shown in FIG. 2) by using a switch K1n. The control unit may be connected to the battery cluster and each DC/DC conversion module by using a control bus. The control unit is configured to control turn-on or turn-off of a switch used by the battery cluster to connect to each DC/DC conversion module, to enable a connection between the battery cluster and one or more DC/DC conversion modules, thereby controlling a rated charge/discharge rate of the energy storage system. For example, n is equal to 2. In this case, when the control unit controls the battery cluster to correspondingly connect to one DC/DC conversion module, the rated charge/discharge rate of the energy storage system is XC; or when the control unit controls the battery cluster to correspondingly connect to two DC/DC conversion modules, the rated charge/discharge rate of the energy storage system is 2XC.

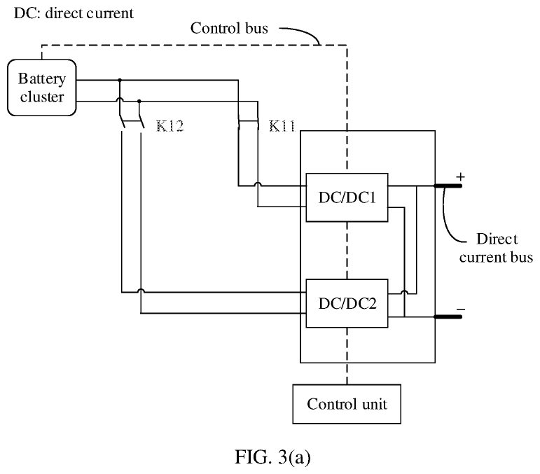

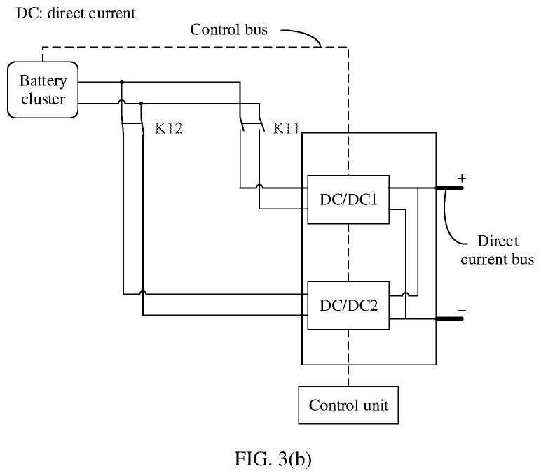

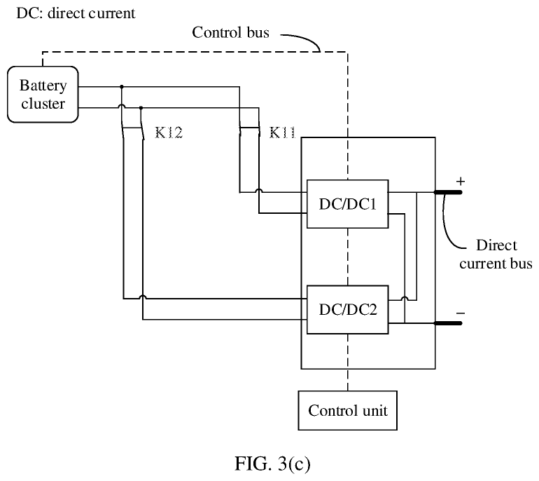

For ease of understanding, refer to FIG. 3(a) to FIG. 3(c). FIG. 3(a) to FIG. 3(c) are a schematic diagram of an application scenario of different rated charge/discharge rates according to an embodiment of this application. As shown in FIG. 3(a) to FIG. 3(c), the energy storage system includes one battery cluster and two DC/DC conversion modules (the DC/DC1 shown in FIG. 2 and DC/DC2). When the control unit controls the switch K11 to be turned on and the switch K12 to be turned off (as shown in FIG. 3(a)), or when the control unit controls the switch K12 to be turned on and the switch K11 to be turned off (as shown in FIG. 3(b)), the rated charge/discharge rate of the energy storage system is XC. When the control unit controls both the switch K11 and the switch K12 to be turned on (as shown in FIG. 3(c)), the rated charge/discharge rate of the energy storage system is 2XC. In other words, when the rated charge/discharge rate of the energy storage system is XC, the one battery cluster in the energy storage system is correspondingly connected to one DC/DC conversion module; when the rated charge/discharge rate of the energy storage system is 2XC, the one battery cluster in the energy storage system is correspondingly connected to two DC/DC conversion modules.

Optionally, in some feasible implementations, when the energy storage system includes at least two battery clusters, an output end of each of the at least two battery clusters may be connected to an input end of each DC/DC conversion module by using a switch. The control unit is connected to each battery cluster and each DC/DC conversion module by using a control bus. The control unit is configured to control turn-on or turn-off of a switch used by each battery cluster to connect to each DC/DC conversion module, to enable connections between different battery clusters and different DC/DC conversion modules. For example, an output end of each of the at least two battery clusters is connected to an input end of each of the at least two DC/DC conversion modules by using a switch, and output ends of the at least two DC/DC conversion modules are connected in parallel to a direct current bus. The control unit is connected to the at least two battery clusters and each of the at least two DC/DC conversion modules by using the control bus, to control charging and discharging of the at least two battery clusters and control each of the at least two DC/DC conversion modules to perform direct current conversion. The control unit is further configured to control turn-on or turn-off of a switch used by each of the at least two battery clusters to connect to each of the at least two DC/DC conversion modules, to control connections between each of the at least two battery clusters and different quantities of DC/DC conversion modules, thereby controlling a rated charge/discharge rate of the energy storage system.

It can be understood that an example in which the energy storage system includes at least two battery clusters and the at least two battery clusters include a first battery cluster and a second battery cluster is used. The control unit is configured to control a switch, which is used by the first battery cluster to connect to h DC/DC conversion modules in the at least two DC/DC conversion modules, to be turned on, control a switch, which is used by the first battery cluster to connect to a DC/DC conversion module that is other than the h DC/DC conversion modules and that is in the at least two DC/DC conversion modules, to be turned off, and control a switch, which is used by the second battery cluster to connect to each of the at least two DC/DC conversion modules, to be turned off, thereby controlling a charge/discharge current of the energy storage system, so that the rated charge/discharge rate of the energy storage system is a target rated charge/discharge rate, where h is an integer greater than 0. For example, if one battery cluster is correspondingly connected to one DC/DC conversion module (e.g., h=1), the rated charge/discharge rate of the energy storage system is XC; or if one battery cluster is correspondingly connected to two DC/DC conversion modules (e.g., h=2), the rated charge/discharge rate of the energy storage system is 2XC. A magnitude of X is determined based on specifications of the battery cluster and the DC/DC conversion module. In other words, if a battery cluster in the energy storage system does not join in running, e.g., the battery cluster is not correspondingly connected to any DC/DC conversion module, a quantity of DC/DC conversion modules correspondingly connected to each running battery cluster is controlled to be 1 or greater than 1, so that different rated charge/discharge rates of the energy storage system can also be controlled.

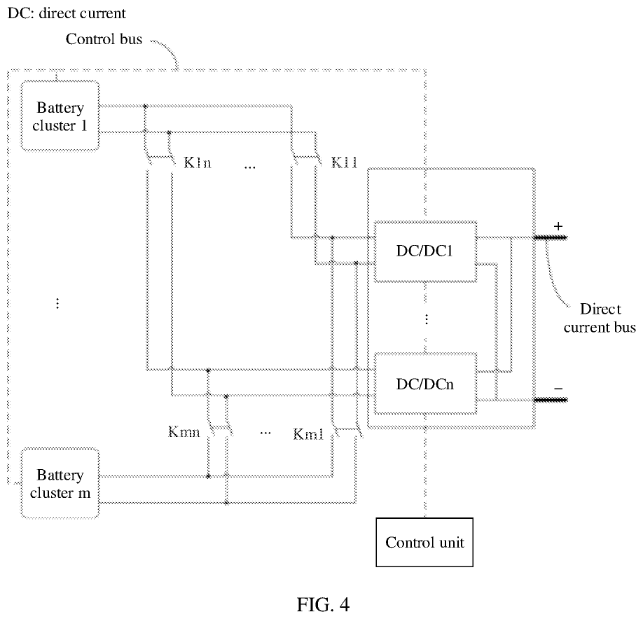

For ease of understanding, refer to FIG. 4. FIG. 4 is a schematic diagram of another structure of an energy storage system according to this application. As shown in FIG. 4, the energy storage system includes m battery clusters, n DC/DC conversion modules, and a control unit, where m is an integer greater than or equal to 1, and n is an integer greater than 1. Herein, an example in which m is an integer greater than 1 is used for description. The m battery clusters may be a battery cluster 1, . . . , and a battery cluster m. The n DC/DC conversion modules may be a DC/DC conversion module 1, . . . , and a DC/DC conversion module n. An output end of the battery cluster 1 may be connected to the DC/DC conversion module 1 (DC/DC1 shown in FIG. 4) by using a switch K11, the output end of the battery cluster 1 may be further connected to a DC/DC conversion module 2 (not shown in FIG. 4) by using a switch K12 (not shown in FIG. 4), . . . , and the output end of the battery cluster 1 may be further connected to the DC/DC conversion module n (DC/DCn shown in FIG. 4) by using a switch K1n. An output end of a battery cluster 2 (not shown in FIG. 4) may be connected to the DC/DC conversion module 1 by using a switch K21 (not shown in FIG. 4), the output end of the battery cluster 2 may be further connected to the DC/DC conversion module 2 by using a switch K22 (not shown in FIG. 4), . . . , and the output end of the battery cluster 2 may be further connected to the DC/DC conversion module n by using a switch K2n (not shown in FIG. 4). The rest may be deduced by analogy. An output end of the battery cluster m may be connected to the DC/DC conversion module 1 by using a switch Km1, the output end of the battery cluster m may be further connected to the DC/DC conversion module 2 by using a switch Km2, . . . , and the output end of the battery cluster m may be further connected to the DC/DC conversion module n by using a switch Kmn. The control unit is connected to each battery cluster and each DC/DC conversion module by using a control bus. The control unit is configured to control turn-on or turn-off of a switch used by each battery cluster to connect to each DC/DC conversion module, to enable connections between different battery clusters and different DC/DC conversion modules, thereby controlling a rated charge/discharge rate of the energy storage system.

For example, m is equal to 2, and n is equal to 2. When either of the two battery clusters included in the energy storage system is correspondingly connected to one DC/DC conversion module, or when each battery cluster is correspondingly connected to one different DC/DC conversion module, the rated charge/discharge rate of the energy storage system is XC. When either one of the two battery clusters included in the energy storage system is correspondingly connected to the two DC/DC conversion modules, and the other battery cluster does not run (e.g., the other battery cluster is not correspondingly connected to any DC/DC conversion module), the rated charge/discharge rate of the energy storage system is 2XC.

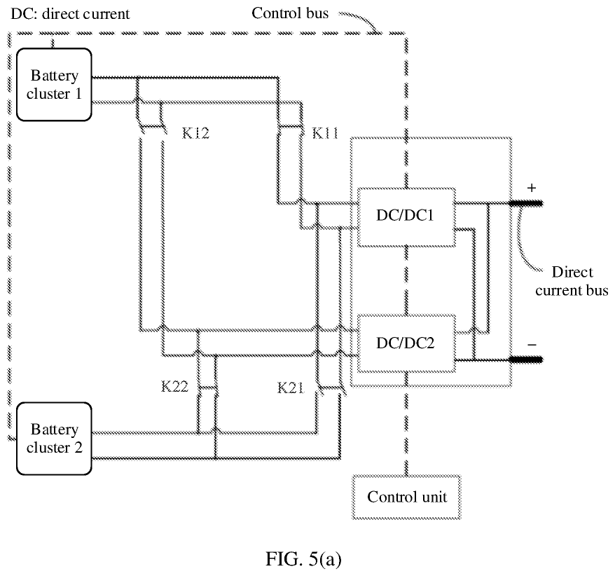

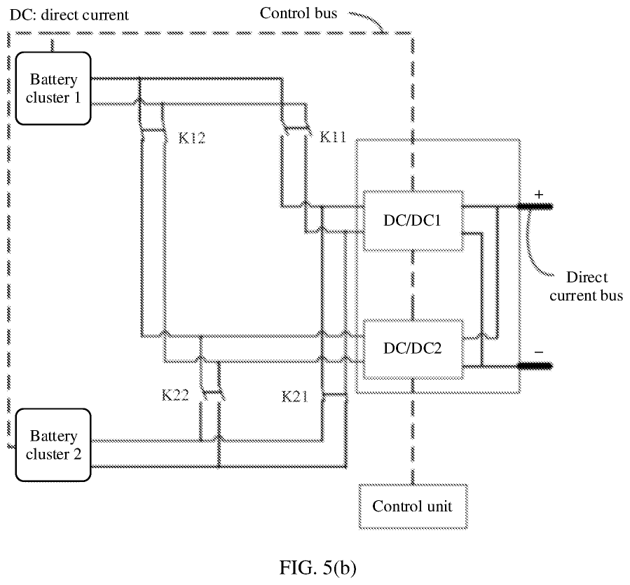

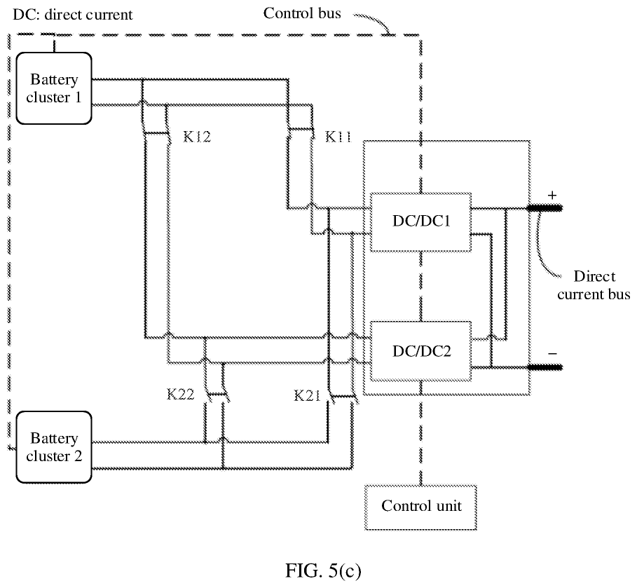

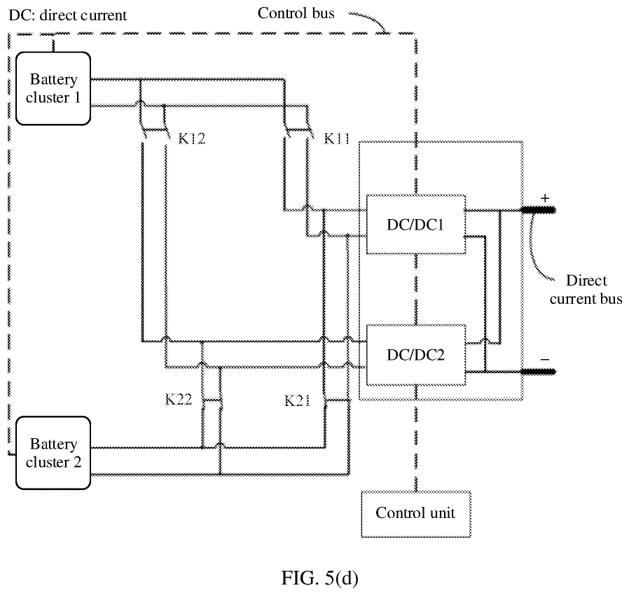

For example, refer to FIG. 5(a) to FIG. 5(d). FIG. 5(a) to FIG. 5(d) are a schematic diagram of another application scenario of different rated charge/discharge rates according to an embodiment of this application. When the control unit controls the switch K11 to be turned on and the switches K12, K21, and K22 to be turned off, or when the control unit controls the switch K12 to be turned on and the switches K11, K21, and K22 to be turned off, or when the control unit controls the switch K21 to be turned on and the switches K11, K12, and K22 to be turned off, or when the control unit controls the switch K22 to be turned on and the switches K11, K12, and K21 to be turned off, or when the control unit controls the switches K11 and K22 to be turned on and the switches K12 and K21 to be turned off (as shown in FIG. 5(a)), or when the control unit controls the switches K12 and K21 to be turned on and the switches K11 and K22 to be turned off (as shown in FIG. 5(b)), the rated charge/discharge rate of the energy storage system is XC. When the control unit controls both the switch K11 and the switch K12 to be turned on and both the switch K21 and the switch K22 to be turned off (as shown in FIG. 5(c)), or when the control unit controls both the switch K21 and the switch K22 to be turned on and both the switch K11 and the switch K12 to be turned off (as shown in FIG. 5(d)), the rated charge/discharge rate of the energy storage system is 2XC. It can be learned from FIG. 5(c) that, when the rated charge/discharge rate of the energy storage system is 2XC, the battery cluster 1 is correspondingly connected to the two DC/DC conversion modules, and the battery cluster 2 is not correspondingly connected to any DC/DC conversion module, e.g., the battery cluster 2 does not run. It can be learned from FIG. 5(d) that, when the rated charge/discharge rate of the energy storage system is 2XC, the battery cluster 2 is correspondingly connected to the two DC/DC conversion modules, and the battery cluster 1 is not correspondingly connected to any DC/DC conversion module, e.g., the battery cluster 1 does not run.

For another example, m is equal to 2 (e.g., the two battery clusters are the battery cluster 1 and the battery cluster 2), and n is equal to 4 (e.g., the four DC/DC conversion modules are the DC/DC1, DC/DC2, DC/DC3, and DC/DC4). When either of the two battery clusters included in the energy storage system is correspondingly connected to one DC/DC conversion module, or when each battery cluster is correspondingly connected to one different DC/DC conversion module, the rated charge/discharge rate of the energy storage system is XC. When either of the two battery clusters included in the energy storage system is correspondingly connected to two DC/DC conversion modules, or when each battery cluster is correspondingly connected to a different pair of DC/DC conversion modules, the rated charge/discharge rate of the energy storage system is 2XC. Optionally, when either one of the at least two battery clusters included in the energy storage system is correspondingly connected to three DC/DC conversion modules, and the other battery cluster does not run, the rated charge/discharge rate of the energy storage system is 3XC; or when either one of the at least two battery clusters included in the energy storage system is correspondingly connected to the four DC/DC conversion modules, and the other battery cluster does not run, the rated charge/discharge rate of the energy storage system is 4XC.

Optionally, in some feasible implementations, to meet an actual power supply requirement of an electric device, the battery cluster in the energy storage system may include battery modules connected in series, in parallel, or in a series-parallel manner. This is specifically determined based on an actual application scenario, and is not limited herein. All the embodiments of this application are described by using an example in which all battery modules in a battery cluster are connected in series. Specifically, each battery cluster may include at least one battery module connected in series. Each battery module includes one battery management unit (BMU). Therefore, the control unit may be connected to a BMU of each battery module in each battery cluster by using the control bus, and the control unit is configured to obtain an initial state of charge (SOC) of each battery cluster by using a BMU of each battery module. Usually, all battery modules in a same battery cluster have a same model and a same initial state of charge, e.g., the initial state of charge of each battery module is also an initial state of charge of the battery cluster.

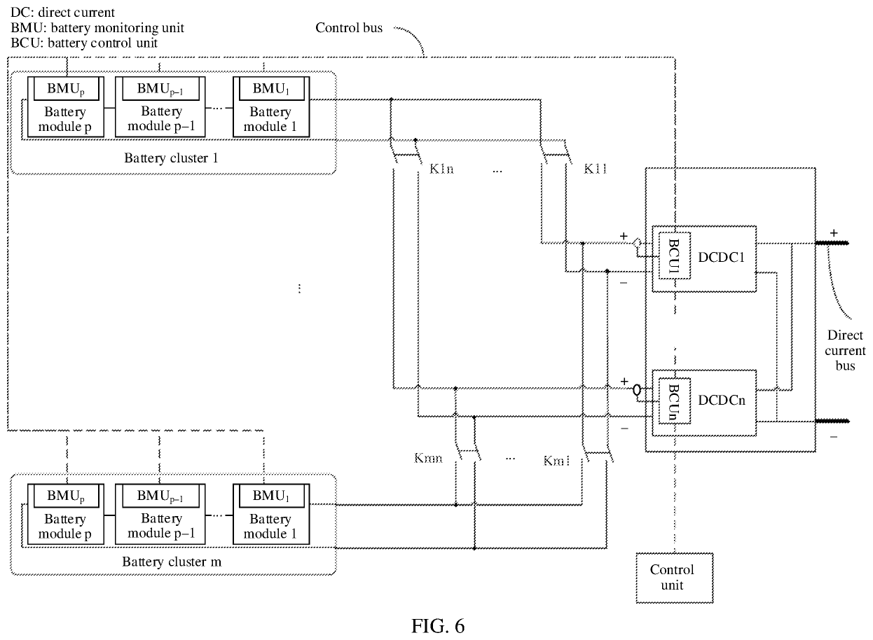

Optionally, in some feasible implementations, each of the at least two DC/DC conversion modules may include one battery control unit BCU, the control unit is connected to each BCU in each DC/DC conversion module by using the control bus, and the control unit is configured to obtain an output current magnitude of each battery cluster by using each BCU. For example, the BCU in this application is integrated into the DC/DC conversion module, to collect a current flowing through a DC/DC battery side (e.g., an output current magnitude of the battery cluster), communicate with the BMU, the control unit, and the like, calculate an SOC, manage a battery module in each battery cluster, and the like. This is not limited herein. For ease of understanding, refer to FIG. 6. FIG. 6 is a schematic diagram of another structure of an energy storage system according to this application. As shown in FIG. 6, the energy storage system includes m battery clusters, n DC/DC conversion modules, and a control unit, where both m and n are integers greater than 1. An output end of each of the m battery clusters is connected to an input end of each DC/DC conversion module by using a switch. Each of the m battery clusters includes p battery modules connected in series, where p is an integer greater than 0. Each battery module includes one BMU, to collect signals such as a cell voltage, a temperature, an initial SOC, and a state of health (state of health, SOH) value in the battery module. Each of the n DC/DC conversion modules includes one BCU. All BMUs included in each battery cluster are connected to a BMU in any DC/DC conversion module in a hand-in-hand communications connection manner. All BMUs included in each DC/DC conversion module may also be connected to the control unit in a hand-in-hand communications connection manner. It can be understood that, in this application, a communication type between the BMU, the BCU, and the control unit may be a daisy chain, a CAN, Wi-Fi, or the like. This is not limited herein. The control unit may estimate information such as a current state of charge of the battery cluster based on an initial state of charge collected by the BMU and a current collected by the BCU.

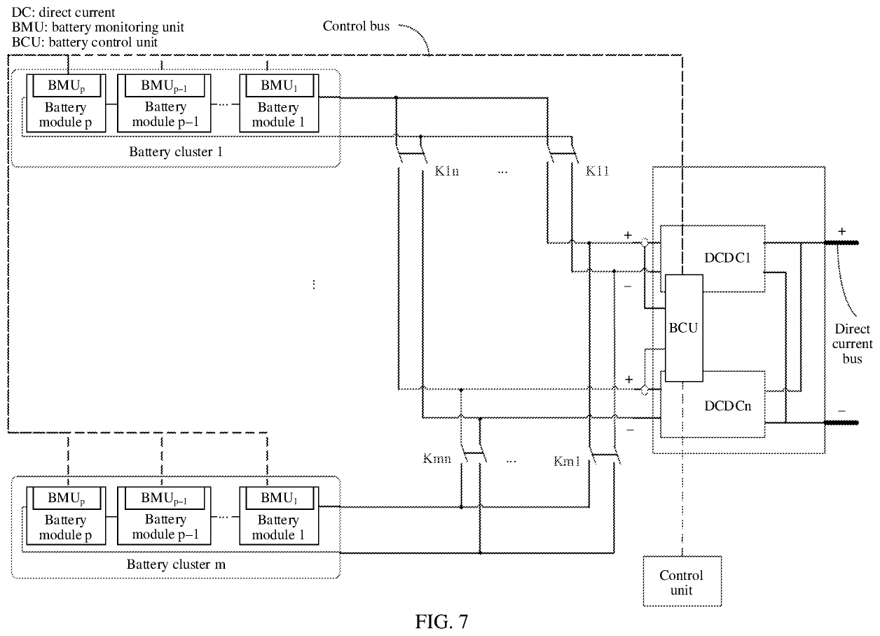

Optionally, in some feasible implementations, alternatively, the at least two DC/DC conversion modules may include one battery control unit BCU, the control unit is connected to the BCU by using a control bus, and the control unit is configured to obtain an output current magnitude of each battery cluster by using the BCU. In other words, the plurality of DC/DC conversion modules included in the energy storage system may alternatively reuse one BCU. The BCU may be configured to collect an output current of each battery cluster, communicate with the BMU, the control unit, and the like, calculate an SOC, manage a battery module in each battery cluster, and the like. This is not limited herein. For ease of understanding, refer to FIG. 7. FIG. 7 is a schematic diagram of another structure of an energy storage system according to this application. As shown in FIG. 7, the energy storage system includes m battery clusters, n DC/DC conversion modules, and a control unit, where both m and n are integers greater than 1. An output end of each of the m battery clusters is connected to an input end of each DC/DC conversion module by using a switch. Each of the m battery clusters includes p battery modules connected in series, where p is an integer greater than 0. Each battery module includes one BMU, to collect signals such as a cell voltage, a temperature, an initial SOC, and an SOH in the battery module. The n DC/DC conversion modules reuse one BCU. All BMUs included in each battery cluster are connected to the BCU in a hand-in-hand communications connection manner, and the BCU is connected to the control unit by using a control bus. The control unit may estimate information such as a current state of charge of the battery cluster based on an initial state of charge collected by the BMU and a current collected by the BCU. It can be understood that, when all the DC/DC conversion modules reuse one BCU, all BMUs in each battery cluster may be connected to the BCU in a hand-in-hand communications connection manner. Then, a current state of charge of each battery cluster is estimated based on an output current of the battery cluster collected by the BCU and an initial state of charge of the battery cluster, to control charging and discharging of each battery cluster based on a current state of charge of the battery cluster, thereby balancing remaining power of each battery cluster. It can be understood that the BMU, the BCU, the control unit, and the like in the embodiments of this application constitute a BMS, and this is different from a related technology in which charging and discharging control is performed on an energy storage system by using an external BMS. The energy storage system provided in this application has a higher degree of integration and higher compatibility.

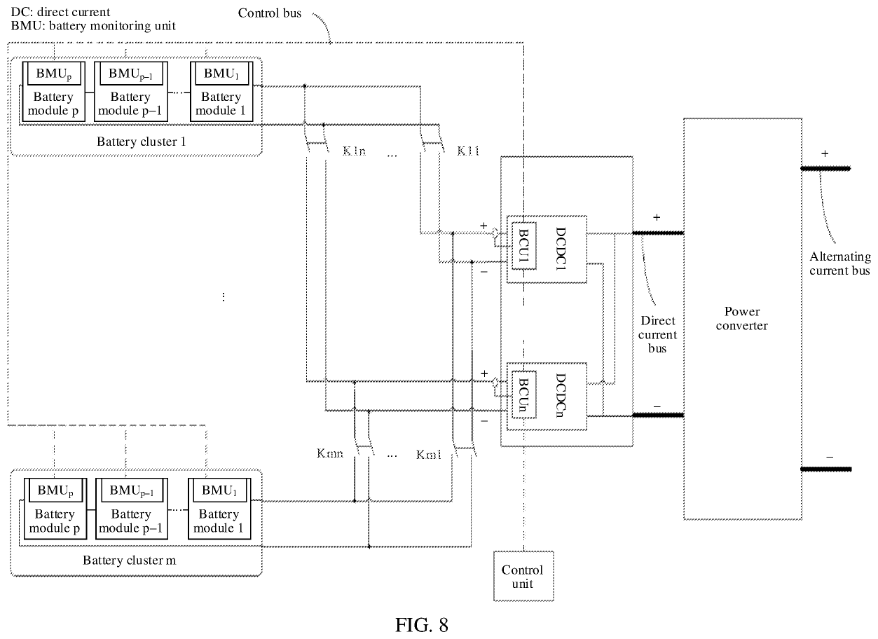

Optionally, in some feasible implementations, the energy storage system may further include a power converter. For example, refer to FIG. 8. FIG. 8 is a schematic diagram of another structure of an energy storage system according to this application. As shown in FIG. 8, an input end of a power converter is connected to a direct current bus, and an output end of the power converter is connected to an alternating current bus. The power converter is configured to convert, into alternating current electricity during discharging of a battery cluster, direct current electricity that is input based on the direct current bus, or the power converter is configured to convert, into direct current electricity during charging of a battery cluster, alternating current electricity that is input based on the alternating current bus. Usually, the power converter may be further connected to a transformer, a power grid, or an alternating current load by using the alternating current bus. Therefore, during discharging of the battery cluster, the battery cluster in the energy storage system may provide a direct current input voltage for each DC/DC conversion module connected to the battery cluster, and the DC/DC conversion module performs power conversion on the direct current input voltage and outputs direct current electric energy to the power converter. In this case, the power converter may perform power conversion on direct current electric energy that is input from each DC/DC conversion module, and output alternating current electric energy to the power grid or the alternating current load (for example, a household device), so as to supply power to the power grid or the alternating current load. The power converter may be a neutral-point-clamped T-type three-level inverter, an active neutral-point-clamped inverter, a flying capacitor multilevel inverter, or the like. This is not limited herein. It can be understood that the energy storage system in this application may include at least one power converter. A specification of the selected power converter may be determined based on an actual application scenario. This is not limited herein.

In the embodiments of this application, turn-on and turn-off of switches used for connections between the battery cluster and the DC/DC conversion modules are controlled by using the control unit, so as to control a quantity of DC/DC conversion modules correspondingly connected to the battery cluster, thereby controlling the rated charge/discharge rate of the energy storage system, to adapt to scenarios requiring various rated charge/discharge rates. This reduces development costs of an energy storage system with different rated charge/discharge rates. In addition, the energy storage system can further implement independent charging and discharging control of each battery cluster, to implement battery balancing, e.g., balance remaining power of each battery cluster, thereby avoiding battery damage caused by overcharge or overdischarge of a battery cluster. This improves reliability and stability of the energy storage system.

The following describes in detail an energy storage system control method provided in this application.

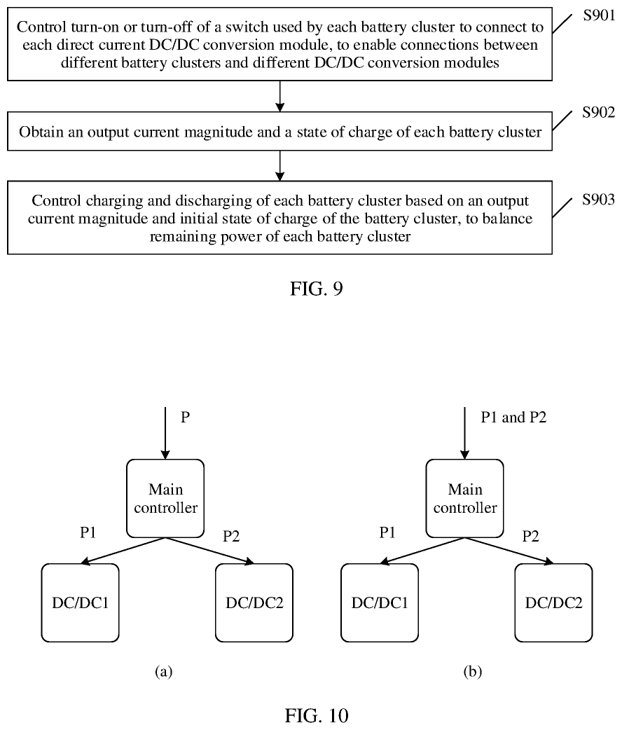

FIG. 9 is a schematic flowchart of an energy storage system control method according to this application. The method is applicable to an energy storage system (for example, the energy storage system provided in FIG. 2 to FIG. 8). For ease of description, in this embodiment of this application, the energy storage system shown in FIG. 4 is used as an example for description. The energy storage system includes at least two battery clusters, at least two direct current DC/DC conversion modules, and a control unit. An output end of each of the at least two battery clusters is connected to an input end of each DC/DC conversion module by using a switch. Output ends of the at least two DC/DC conversion modules are connected in parallel to a direct current bus. The control unit is connected to each battery cluster and each DC/DC conversion module by using a control bus. As shown in FIG. 9, the method includes step S901 to step S903 below.

S901: Control turn-on or turn-off of a switch used by each battery cluster to connect to each DC/DC conversion module, to enable connections between different battery clusters and different DC/DC conversion modules.

In some feasible implementations, the control unit may send a switch control instruction, thereby controlling turn-on or turn-off of a switch used by each battery cluster to connect to each DC/DC conversion module, to enable connections between different battery clusters and different DC/DC conversion modules. For example, with reference to FIG. 5(a) to FIG. 5(d), the energy storage system includes two battery clusters and two DC/DC conversion modules. It is assumed that the two battery clusters are a battery cluster 1 and a battery cluster 2, and the two DC/DC conversion modules are DC/DC1 and DC/DC2. As shown in FIG. 5(a) to FIG. 5(d), an output end of the battery cluster 1 may be connected to the DC/DC conversion module 1 (the DC/DC1 shown in FIG. 5(a) to FIG. 5(d)) by using the switch K11, and the output end of the battery cluster 1 may be further connected to the DC/DC conversion module 2 (the DC/DC2 shown in FIG. 5(a) to FIG. 5(d)) by using the switch K12; and an output end of the battery cluster 2 may be connected to the DC/DC conversion module 1 (the DC/DC1 shown in FIG. 5(a) to FIG. 5(d)) by using the switch K21, and the output end of the battery cluster 2 may be further connected to the DC/DC conversion module 2 (the DC/DC2 shown in FIG. 5(a) to FIG. 5(d)) by using the switch K22. When the control unit turns on the switch K11 and the switch K22 and turns off the switch K12 and the switch K21 (as shown in FIG. 5(a)) by using the switch control instruction, or turns on the switch K12 and the switch K21 and turns off the switch K11 and the switch K22 (as shown in FIG. 5(b)) by using the switch control instruction, a rated charge/discharge rate of the energy storage system is XC. When the control unit turns on the switch K11 and the switch K12 and turns off the switch K21 and the switch K22 (as shown in FIG. 5(c)) by using the switch control instruction, or when the control unit turns on the switch K21 and the switch K22 and turns off the switch K11 and the switch K12 (as shown in FIG. 5(d)) by using the switch control instruction, a rated charge/discharge rate of the energy storage system is 2XC.

S902: Obtain an output current magnitude and initial state of charge of each battery cluster.

In some feasible implementations, the control unit may obtain an output current magnitude and initial state of charge of each battery cluster. Specifically, the control unit may use a BCU in the DC/DC conversion module to collect an output current magnitude of each battery cluster, and use a BMU in each battery module in each battery cluster to collect an initial state of charge of the battery module. In this embodiment of this application, each battery cluster includes at least one battery module connected in series. Usually, all battery modules in a same battery cluster are of a same model and have a same initial state of charge, e.g., an initial state of charge of each battery module in a same battery cluster is equivalent to an initial state of charge of the battery cluster. Therefore, the control unit may determine, as an initial state of charge of the battery cluster, an initial state of charge of any battery module obtained by using a BMU. The BCU in the DC/DC conversion module may be configured to collect an output current of each battery cluster. Therefore, the control unit may obtain an output current magnitude of each battery cluster by using each BCU. Optionally, when the plurality of DC/DC conversion modules reuse one BCU, an output current magnitude of each battery cluster may be obtained based on the one BCU. This is specifically determined based on an actual application scenario, and is not limited herein.

S903: Control charging and discharging of each battery cluster based on an output current magnitude and initial state of charge of the battery cluster, to balance remaining power of each battery cluster.

In some feasible implementations, the control unit may control charging and discharging of each battery cluster based on an output current magnitude and initial state of charge of the battery cluster, to balance remaining power of each battery cluster. Specifically, the controlling charging and discharging of each battery cluster based on an output current magnitude and initial state of charge of the battery cluster may be understood as: controlling, based on an output current magnitude and initial state of charge of each battery cluster, operating power of each DC/DC conversion module correspondingly connected to the battery cluster, to control charging and discharging of each battery cluster. The controlling, based on an output current magnitude and initial state of charge of each battery cluster, operating power of each DC/DC conversion module correspondingly connected to the battery cluster may be understood as: determining, based on an output current magnitude and initial state of charge of any battery cluster, a first state of charge corresponding to the any battery cluster; and controlling, based on a first state of charge corresponding to each battery cluster, operating power of each DC/DC conversion module correspondingly connected to the battery cluster, to control charging and discharging of each battery cluster.

For ease of understanding, the following describes in detail a process of estimating the first state of charge.

In some feasible implementations, a BMU integrated in a battery module of each battery cluster records an initial state of charge of the battery module. Usually, all battery modules in a same battery cluster have a same model and a same initial state of charge, e.g., the initial state of charge of each battery module is also an initial state of charge of the battery cluster. It can be understood that a BCU in each DC/DC conversion module may independently sample a current flowing through a DC/DC battery side. For example, with reference to FIG. 5(a) to FIG. 5(d), the energy storage system includes two DC/DC conversion modules (e.g., the DC/DC1 and the DC/DC2). A BCU1 in the DC/DC1 and a BCU2 in the DC/DC2 may respectively collect currents I₁ and I₂ at a first sampling interval t1 and a second sampling interval t2, and then the collected currents are accumulated, to calculate state-of-charge variations ΔSOC1 and ΔSOC2. Specifically, ΔSOC1 and ASOC2 satisfy the following:

$$\{ \begin{matrix}Δ S O C 1 = {\sum }_{0}^{N 1} {I}_{1}^{*} {t}_{1} / {Ah}_{0} \\ Δ S O C 2 = {\sum }_{0}^{N 2} {I}_{2}^{*} {t}_{2} / {Ah}_{0}\end{matrix}$$

Herein, N1 represents a quantity of current sampling times of the BCU1, N2 represents a quantity of current sampling times of the BCU2, and Aho represents a rated battery capacity.

For ease of understanding, the energy storage system shown in FIG. 5(a) to FIG. 5(d) is used as an example. It is assumed that the energy storage system shown in FIG. 5(a) to FIG. 5(d) is a 2XC system (e.g., the rated charge/discharge rate of the energy storage system is 2XC). In this case, currents sampled by the BCU1 and the BCU2 are actually from a same battery cluster (which may be, for example, the battery cluster 1 (as shown in FIG. 5(c)) or the battery cluster 2 (as shown in FIG. 5(d))). Therefore, a calculation formula of a current state of charge (e.g., a first state of charge) of the battery cluster is:

SOC=SOC0+ASOC1+ASOC2.

Herein, SOC represents the first state of charge, and SOC0 is an initial state of charge of the battery cluster (e.g., an initial state of charge of any battery module detected by using a BMU).

If the energy storage system is an XC system (e.g., the rated charge/discharge rate of the energy storage system is XC), currents sampled by the BCU1 and the BCU2 are respectively from the battery cluster 1 and the battery cluster 2 (as shown in FIG. 5(a)). Therefore, calculation formulas of current states of charge of the battery cluster 1 and the battery cluster 2 are:

$$\{ \begin{matrix}SOC 1 = {SOC}_{0}^{1} + Δ SOC 1 \\ SOC 2 = {SOC}_{0}^{2} + Δ SOC 2\end{matrix} .$$

Herein, SOC1 is a current state of charge of the battery cluster 1 (e.g., a first state of charge corresponding to the battery cluster 1), SOC₀¹ is an initial state of charge of the battery cluster 1, SOC2 is a current state of charge of the battery cluster 2 (e.g., a first state of charge corresponding to the battery cluster 2), and SOC₀² is an initial state of charge of the battery cluster 2.

In some feasible implementations, after determining a first state of charge of each battery cluster, the control unit may control, based on a first state of charge corresponding to each battery cluster, operating power of each DC/DC conversion module correspondingly connected to the battery cluster, to control charging and discharging of each battery cluster. It can be understood that, in this embodiment of this application, each DC/DC conversion module runs independently, but all of the DC/DC conversion modules are controlled by a same main controller. FIG. 10 is a schematic diagram of controlling a DC/DC conversion module according to this application. A main controller in FIG. 10 may be understood as a main controller included in a direct current converter. For ease of understanding, in this embodiment of this application, the energy storage system shown in FIG. 5(a) to FIG. 5(d) is still used as an example for description. The energy storage system includes two battery clusters and two DC/DC conversion modules. The two battery clusters are the battery cluster 1 and the battery cluster 2, and the two DC/DC conversion modules are the DC/DC1 and the DC/DC2. As shown in (a) in FIG. 10, in a 2XC scenario (for example, a scenario shown in FIG. 5(c) or a scenario shown in FIG. 5(d)), only one battery cluster (the battery cluster 1 or the battery cluster 2) in the energy storage system is running, and the battery cluster is correspondingly connected to the two DC/DC conversion modules. Therefore, the main controller may receive one power control instruction P from the control unit, and then evenly allocate the instruction to the DC/DC1 and the DC/DC2, e.g., power control instructions received by the DC/DC1 and the DC/DC2 satisfy P1=P2=P/2. As shown in (b) in FIG. 10, in an XC scenario (for example, a scenario shown in FIG. 5(a) or a scenario shown in FIG. 5(b)), the two battery clusters in the energy storage system are both in a running state, e.g., each battery cluster is correspondingly connected to one DC/DC conversion module. Therefore, the main controller may receive two control instructions P1 and P2 from the control unit, to respectively control operating power of the DC/DC1 and operating power of the DC/DC2. In other words, a quantity of power control instructions received by the main controller from the control unit is the same as a quantity of actually running battery clusters. Power magnitudes indicated by the power control instructions P1 and P2 correspond to the current states of charge (e.g., the first states of charge) of the battery cluster 1 and the battery cluster 2. Specifically, during discharging of the energy storage system, a power control instruction magnitude is directly proportional to an SOC of a battery cluster, e.g., (P1, P2)∝(SOC1, SOC2). During charging of the energy storage system, a power control instruction magnitude is directly proportional to (100%-SOC) of a battery cluster, e.g., (P1, P2)∝(100%-SOC1, 100%-SOC2). In other words, the control unit may control, based on a first state of charge corresponding to each battery cluster, operating power of each DC/DC conversion module correspondingly connected to the battery cluster, to control charging and discharging of each battery cluster, thereby balancing remaining power of each battery cluster.

In this embodiment of this application, the control unit controls turn-on or turn-off of a switch used by each battery cluster to connect to each DC/DC conversion module, to enable connections between different battery clusters and different DC/DC conversion modules, so that the energy storage system can have different rated charge/discharge rates. Further, in an actual running phase, the control unit obtains an output current magnitude and initial state of charge of each battery cluster, and can determine a current state of charge (e.g., a first state of charge) of each battery cluster based on an output current magnitude and initial state of charge of the battery cluster. Then, the control unit controls charging and discharging of each battery cluster based on a current state of charge of the battery cluster, to balance remaining power of each battery cluster, thereby avoiding overcharge and overdischarge of the battery cluster. This helps improve stability and reliability of the energy storage system, and makes the energy storage system more applicable.

The foregoing descriptions are merely specific implementations of the present invention, but are not intended to limit the protection scope of the present invention. Any variation or replacement readily figured out by a person skilled in the art within the technical scope disclosed in the present invention shall fall within the protection scope of the present invention. Therefore, the protection scope of the present invention shall be subject to the protection scope of the claims.

What is claimed is:

1. An energy storage system, comprising:
at least one battery cluster;
at least two direct current/direct current (DC/DC) conversion circuits; and
a controller;
wherein an output end of each of the at least one battery cluster is connected to an input end of each of the at least two DC/DC conversion circuits through a switch, and output ends of the at least two DC/DC conversion circuits are connected in parallel to a direct current bus; and
wherein the controller is connected to the at least one battery cluster and each of the at least two DC/DC conversion circuits through a control bus, the controller being configured to:
control charging and discharging of the at least one battery cluster and control each of the at least two DC/DC conversion circuits to perform direct current conversion; and
control turn-on or turn-off of a respective switch connecting each of the at least one battery cluster to connect to each of the at least two DC/DC conversion circuits, to control connections between each of the at least one battery cluster and different quantities of the at least two DC/DC conversion circuits to control a rated charge/discharge rate of the energy storage system.

2. The energy storage system according to claim 1, wherein:
the at least one battery cluster comprises a first battery cluster; and
the controller is configured to turn-on a first switch connecting the first battery cluster to a first DC/DC conversion circuit of the at least two DC/DC conversion circuits, to be turned on and turn-off a second switch connecting the first battery cluster to a second DC/DC conversion circuit of the at least two DC/DC conversion circuits so that the rated charge/discharge rate of the energy storage system is a first rated charge/discharge rate.

3. The energy storage system according to claim 2, wherein the controller is further configured to turn-on n switches connecting the first battery cluster to n DC/DC conversion circuits in the at least two DC/DC conversion circuits and turn-off a third switch connecting the first battery cluster to connect to a third DC/DC conversion circuit that is other than the n DC/DC conversion circuits and that is in the at least two DC/DC conversion circuits so that the rated charge/discharge rate of the energy storage system is a second rated charge/discharge rate, wherein the n DC/DC conversion circuits or the third DC/DC conversion circuit comprise the first DC/DC conversion circuit, the second rated charge/discharge rate is n times the first rated charge/discharge rate, and n is an integer greater than 1.

4. The energy storage system according to claim 3, wherein the controller is further configured to control charging and discharging of each of the at least one battery cluster based on an output current magnitude and initial state of charge of the battery cluster, to balance remaining power of each battery cluster.

5. The energy storage system according to claim 2, wherein the controller is further configured to control charging and discharging of each of the at least one battery cluster based on an output current magnitude and initial state of charge of the battery cluster, to balance remaining power of each battery cluster.

6. The energy storage system according to claim 1 further comprising at least two battery clusters, the at least two battery clusters comprising a first battery cluster and a second battery cluster, wherein the controller is further configured to:
turn-on a fourth switch connecting the first battery cluster to h DC/DC conversion circuits in the at least two DC/DC conversion circuits; turn-off a fifth switch connecting the first battery cluster to a fourth DC/DC conversion circuit that is other than the h DC/DC conversion circuits and that is in the at least two DC/DC conversion circuits; and turn-off a sixth switch connecting the second battery cluster to each of the at least two DC/DC conversion circuits so that the rated charge/discharge rate of the energy storage system is a target rated charge/discharge rate, wherein h is an integer greater than 0.

7. The energy storage system according to claim 1, wherein the controller is further configured to control charging and discharging of each of the at least one battery cluster based on an output current magnitude and initial state of charge of the at least one battery cluster to balance remaining power of each of the at least one battery cluster.

8. The energy storage system according to claim 7, wherein each of the at least one battery cluster comprises at least one battery module connected in series, each at least one battery module comprises a battery management unit (BMU), the controller is connected to a BMU of each of the at least one battery module in each of the at least one battery cluster through the control bus, and the controller is configured to obtain an initial state of charge of each of the at least one battery cluster by using a BMU of each of the at least one battery module.

9. The energy storage system according to claim 7, wherein each of the at least two DC/DC conversion circuits comprises a battery control unit (BCU), the controller is connected to each BCU in the at least two DC/DC conversion circuits through the control bus, and the controller is configured to obtain an output current magnitude of each of the at least one battery cluster through each BCU.

10. The energy storage system according to claim 7, wherein the at least two DC/DC conversion circuits comprise a battery control unit (BCU), the controller is connected to the BCU through the control bus, and the controller is configured to obtain an output current magnitude of each battery cluster through the BCU.

11. The energy storage system according to claim 1, further comprising a power converter, wherein an input end of the power converter is connected to the direct current bus, an output end of the power converter is connected to an alternating current bus, and the power converter is configured to convert, into alternating current electricity during discharging of the at least one battery cluster, direct current electricity that is input based on the direct current bus, or the power converter is configured to convert, into direct current electricity during charging of the at least one battery cluster, alternating current electricity that is input based on the alternating current bus.

12. An energy storage system control method, comprising:
controlling, by an energy storage system, turn-on or turn-off of a respective switch connecting each of at least one battery cluster to each of at least two direct current/direct current (DC/DC) conversion circuits to control connections between each of the at least one battery cluster and different quantities of the at least two DC/DC conversion circuits, wherein the energy storage system comprises the at least one battery cluster, the at least two DC/DC conversion circuits, and a controller, and wherein an output end of each of the at least one battery cluster is connected to an input end of each of the at least two DC/DC conversion circuits through a switch, and output ends of the at least two DC/DC conversion circuits are connected in parallel to a direct current bus;
obtaining an output current magnitude and initial state of charge of each of the at least one battery cluster; and
controlling charging and discharging of each of the at least one battery cluster based on an output current magnitude and initial state of charge of a respective battery cluster to balance remaining power of each of the at least one battery cluster.

13. The method according to claim 12, wherein the controlling charging and discharging of each of the at least one battery cluster based on an output current magnitude and initial state of charge of the respective battery cluster comprises:
controlling, based on an output current magnitude and initial state of charge of each of the at least one battery cluster, operating power of each DC/DC conversion circuit correspondingly connected to the respective battery cluster, to control charging and discharging of each of the at least one battery cluster.

14. The method according to claim 13, wherein the controlling, based on an output current magnitude and initial state of charge of each of the at least one battery cluster, operating power of each DC/DC conversion circuit correspondingly connected to the respective battery cluster comprises:
determining, based on an output current magnitude and initial state of charge of the respective battery cluster, a first state of charge corresponding to the respective battery cluster; and
controlling, based on a first state of charge corresponding to each of the at least one battery cluster, operating power of each DC/DC conversion circuit correspondingly connected to the respective battery cluster, to control charging and discharging of each of the at least one battery cluster.
